(19) United States
(12) Patent Application Publication
(10) Pub. No.: US 2011/0260788 A1
(43) Pub. Date: Oct. 27, 2011

(54) AMPLIFIER DEVICE AND SENSOR MODULE

(75) Inventors: Fumihito INUKAI, Kyoto (JP); Hitoshi KOBAYASHI, Osaka (JP); Shigeo MASAI, Osaka (JP)

(73) Assignee: PANASONIC CORPORATION, Osaka (JP)

(21) Appl. No.: 13/176,280

(22) Filed: Jul. 5, 2011

Related U.S. Application Data
(63) Continuation of application No. PCT/JP2009/003073, filed on Jul. 2, 2009.

(30) Foreign Application Priority Data
Feb. 27, 2009 (JP) 2009-046142

(51) Int. Cl. H03F 3/45

(52) U.S. Cl. 330/69

(57) ABSTRACT

A first low-pass filter circuit includes a first input terminal which receives a sensor signal, a second input terminal, and an output terminal which outputs a first output signal. A second low-pass filter circuit includes an input terminal connected to the second input terminal of the first low-pass filter circuit, and an output terminal. A third low-pass filter circuit includes an input terminal connected to the output terminal of the second low-pass filter circuit, and an output terminal which outputs a second output signal.

### CROSS-REFERENCE TO RELATED APPLICATION

This is a continuation of PCT International Application PCT/JP2009/003073 filed on Jul. 2, 2009, which claims priority to Japanese Patent Application No. 2009-046142 filed on Feb. 27, 2009. The disclosures of these applications including the specifications, the drawings, and the claims are hereby incorporated by reference in its entirety.

### BACKGROUND

The technology disclosed in this specification relates to amplifier devices which amplify sensor signals from sensors, and sensor modules including the same.

Conventionally, capacitive sensor elements (sensor elements used as microphones), angular velocity sensor elements (sensor elements for vibration compensation in digital cameras), etc. are used in portable devices. Such sensor elements are used with amplifier devices which amplify outputs of the sensor elements to form sensor modules. In order to improve performance of such sensor modules, noise reduction in the amplifier devices is essential, and in particular, if the sensor modules are used in portable devices, reduction in power consumption and in size of the amplifier devices is required as well. Note that output signals of a sensor module are used after converting the output signals into a digital signal using an analog-to-digital converter (ADC).

U.S. Pat. No. 6,583,658 discloses an amplifier device which converts a sensor signal received from a microphone to a differential output signal. This amplifier device includes a first operational amplifier having a non-inverting input terminal which receives a sensor signal, and a second operational amplifier having an inverting input terminal which receives an output signal of the first operational amplifier through a first resister. The output terminal of the first operational amplifier is connected to the inverting input terminal of the first operational amplifier, the non-inverting input terminal of the second operational amplifier is connected to a ground node, and the output terminal of the second operational amplifier is connected through a second resistor to the non-inverting input terminal of the second operational amplifier. That is, the first operational amplifier forms a voltage follower, and the second operational amplifier forms an inverting amplifier. An ADC converts the outputs (differential signals) of the first and the second operational amplifiers to a digital signal.

### SUMMARY

According to U.S. Pat. No. 6,583,658, when the frequency of the differential signal is higher than the sampling frequency of the ADC, high frequency components are folded into low frequency components of the digital signal. Thus, in order to increase the resolution of the ADC, high frequency components need to be attenuated in a stage preceding the ADC. In addition, inputting a DC offset to the ADC (in particular, delta-sigma ADC) substantially reduces the dynamic range. Moreover, due to the possible presence of a sensor element having a high sensitivity to low frequency signals, such as a microphone, low frequency components also need to be attenuated in a stage preceding the ADC. Accordingly, a bandpass filter needs to be provided before the ADC to limit the signal bandwidth. However, since a bandpass filter usually includes many elements such as operational amplifiers, usage of a bandpass filter causes thermal noise, power consumption, and a mounting area to be increased. Therefore, it has been difficult to reduce noise, power consumption, and a circuit area with respect to a sensor module.

Thus, It is an object of the technology disclosed in this specification to provide an amplifier device which requires no bandpass filters therein.

According to one embodiment of the present invention, an amplifier device for amplifying a sensor signal from a sensor includes a first low-pass filter circuit having a first input terminal which receives the sensor signal, a second input terminal, and an output terminal which outputs a first output signal, a second low-pass filter circuit having an input terminal connected to the second input terminal of the first low-pass filter circuit, and an output terminal, and a third low-pass filter circuit having an input terminal connected to the output terminal of the second low-pass filter circuit, and an output terminal which outputs a second output signal. With such a configuration, the amplifier device can have a characteristic of a bandpass filter, and thus there is no need to provide a bandpass filter. Accordingly, noise, power consumption, and a circuit area can be reduced.

The first low-pass filter circuit may be an active filter, the second low-pass filter circuit may be a passive filter, and the third low-pass filter circuit may be an active filter.

Moreover, the first low-pass filter circuit may amplify frequency components lower than a first cut-off frequency, of a differential voltage signal which depends on a voltage difference between signals respectively provided to the first and the second input terminals of the first low-pass filter circuit, and output a resultant signal through the output terminal of the first low-pass filter circuit as the first output signal. The second low-pass filter circuit may output frequency components lower than a second cut-off frequency, of a signal provided to the input terminal of the second low-pass filter circuit, through the output terminal of the second low-pass filter circuit. The third low-pass filter circuit may amplify frequency components lower than a third cut-off frequency, of a signal provided to the input terminal of the third low-pass filter circuit, and output a resultant signal through the output terminal of the third low-pass filter circuit as the second output signal.

### BRIEF DESCRIPTION OF THE DRAWINGS

FIG. 1 is a diagram illustrating an example configuration of an amplifier device according to the first embodiment.

FIGS. 2A, 2B, and 2C are diagrams to explain frequency characteristics of the amplifier device shown in FIG. 1.

FIG. 3 is a diagram illustrating an example configuration of the ADC shown in FIG. 1.

FIG. 4 is a diagram illustrating an example configuration of an amplifier device according to the second embodiment.

FIG. 5 is a diagram illustrating an example configuration of an amplifier device according to the third embodiment.

FIGS. 6A, 6B, and 6C are diagrams to explain frequency characteristics of the amplifier device shown in FIG. 5.

FIG. 7 is a diagram to explain a variation of the amplifier device shown in FIG. 5.

FIG. 8 is a diagram to explain another variation of the amplifier device shown in FIG. 5.

### DETAILED DESCRIPTION

Example embodiments will be described below in detail with reference to the drawings, in which like reference characters indicate the same or equivalent components, and the explanation thereof will be omitted.

### First Embodiment

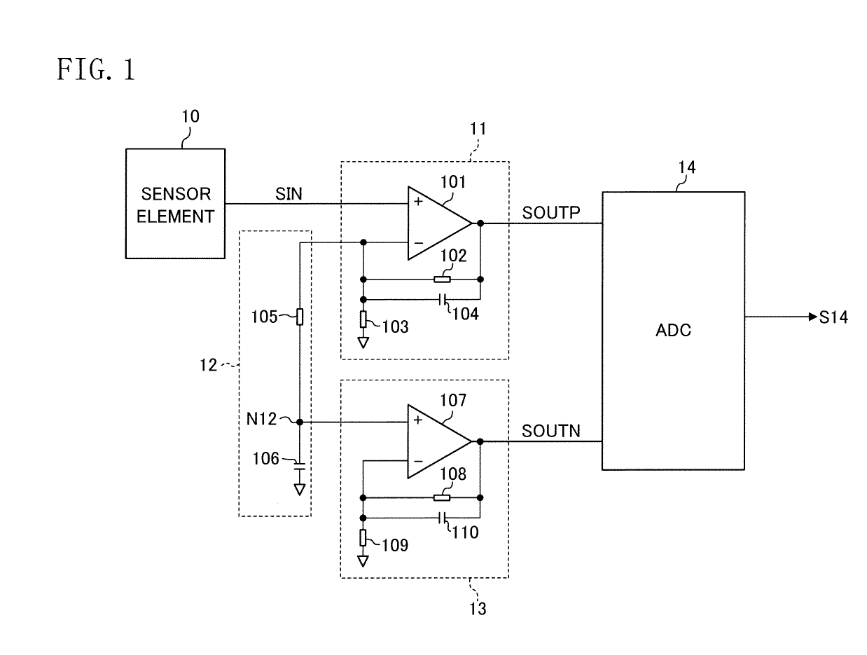

FIG. 1 illustrates an amplifier device according to the first embodiment. The amplifier device amplifies a sensor signal SIN from a sensor 10, and provides the resultant signal to an analog-to-digital converter (ADC) 14. The amplifier device includes low-pass filter circuits 11, 12, and 13. The low-pass filter circuits 11, 12, and 13, and the ADC 14 are a part of a sensor module.

The low-pass filter circuit 11 (first low-pass filter circuit) includes an operational amplifier 101 having the non-inverting input terminal, which receives the sensor signal SIN, a resistor 102 connected between the output terminal and the inverting input terminal of the operational amplifier 101, a resistor 103 connected between the inverting input terminal of the operational amplifier 101 and a reference node (here, a ground node), and a capacitor 104 connected between the output terminal and the inverting input terminal of the operational amplifier 101. That is, the low-pass filter circuit 11 is an active filter, which amplifies frequency components lower than a predetermined cut-off frequency (cut-off frequency determined by the resistor 102 and the capacitor 104), of a differential voltage signal which depends on a voltage difference between signals respectively provided to the non-inverting and the inverting input terminals of the operational amplifier 101, and outputs the resultant signal through the output terminal of the operational amplifier 101 as an output signal SOUTP.

The low-pass filter circuit 12 (second low-pass filter circuit) includes a resistor 105 connected between the inverting input terminal of the operational amplifier 101 and an output node N12, and a capacitor 106 connected between the output node N12 and the reference node. That is, the low-pass filter circuit 12 is a passive filter, which outputs frequency components lower than a predetermined cut-off frequency (cut-off frequency determined by the resistor 105 and the capacitor 106), of a signal provided to the input terminal (corresponding end of the resistor 105), through the output node N12.

The low-pass filter circuit 13 (third low-pass filter circuit) includes an operational amplifier 107 having the non-inverting input terminal connected to the output node 12, a resistor 108 connected between the output terminal and the inverting input terminal of the operational amplifier 107, a resistor 109 connected between the inverting input terminal of the operational amplifier 107 and the reference node, and a capacitor 110 connected between the output terminal and the inverting input terminal of the operational amplifier 107. That is, the low-pass filter circuit 13 is an active filter, which amplifies frequency components lower than a predetermined cut-off frequency (cut-off frequency determined by the resistor 108 and the capacitor 110), of a signal provided to the non-inverting input terminal of the operational amplifier 107, and output the resultant signal through the output terminal of the operational amplifier 107 as an output signal SOUTN.

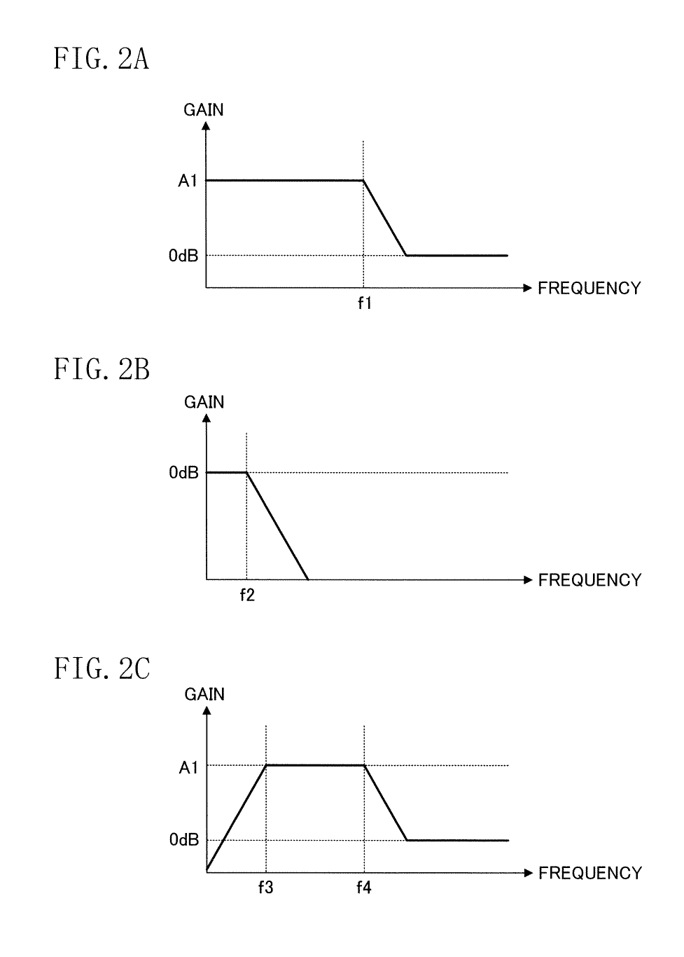

Next, frequency characteristics of the amplifier device shown in FIG. 1 will be described. The DC gain of the low-pass filter circuit 11 is determined by the ratio between the resistors 102 and 103, and the DC gain of the low-pass filter circuit 13 is determined by the ratio between the resistors 108 and 109. Here, it is assumed that as shown in FIG. 2A, the DC gains of the low-pass filter circuits 11 and 13 are each a gain value A1, and the cut-off frequencies of the low-pass filter circuits 11 and 13 are each a frequency f1. In addition, it is assumed that as shown in FIG. 2B, the DC gain of the low-pass filter circuit 12 is 0 dB, and the cut-off frequency thereof is a frequency f2. In such a case, as shown in FIG. 2C, the amplifier device exhibits a frequency characteristic of a bandpass filter. The lower cut-off frequency f3 corresponds to the cut-off frequency t2 of the low-pass filter circuit 12, and the higher cut-off frequency f4 corresponds to the cut-off frequency f1 of the low-pass filter circuit 11. The lower the frequency of the sensor signal SIN is than the cut-off frequency f3 (alternatively, the higher the frequency is than the cut-off frequency f4), the amplitude of the differential signal (SOUTP-SOUTN) is small. That is, these frequency components of the sensor signal SIN are attenuated.

Thus, providing the amplifier device having a characteristic of a bandpass filter eliminates the necessity of providing a bandpass filter, and thus allows the number of operational amplifiers in a sensor module to be reduced as compared with conventional ones; accordingly, noise, power consumption, and a circuit area can be reduced.

In addition, since the sensor signal SIN is directly provided to the non-inverting input terminal of the operational amplifier 101, configuring the operational amplifier 101 using a CMOS circuit allows the input impedance to be set to greater than or equal to 1 M. Accordingly, the input leak current can be reduced, and thus the accuracy of detecting the sensor signal SIN can be improved.

Note that the DC gains of the low-pass filter circuits 11 and 13 may be different from each other; however, since a larger difference between the DC gains results in a smaller amount of attenuation of low frequency components, it is preferable that the DC gains of the low-pass filter circuits 11 and 13 be the same (or almost the same). Moreover, the cut-off frequencies of the low-pass filter circuits 11 and 13 may be frequencies different from each other.

[Example Configuration of ADC]

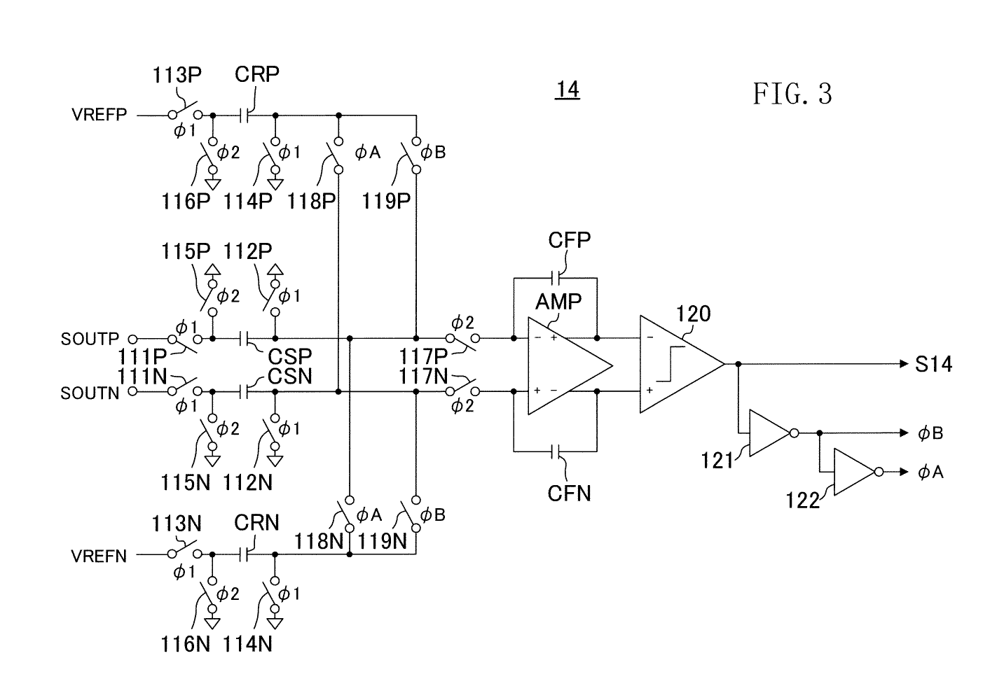

FIG. 3 illustrates an example configuration of the ADC 14 shown in FIG. 1. For example, the ADC 14 is a first-order delta-sigma ADC, which includes switches 111P, 112P, . . . , and 119P, and 111N, 112N, . . . , and 119N, sampling capacitors CSP, CRP, CSN, and CRN, an operational amplifier AMP, feedback capacitors CFP and CFN, a comparator 120, and inverters 121 and 122. The switches 111P, . . . , and 114P, and 111N, . . . , and 114N are turned on/off based on a control clock φ1. The switches 115P, . . . , and 117P, and 115N, . . . , and 117N are turned on/off based on a control clock φ2 (inverted clock of the control clock φ1). The switches 118P and 118N are turned on/off based on a control signal φA (output of the inverter 122). The switches 119P and 119N are turned on/off based on a control signal φB (output of the inverter 121). In this way, on-off operations of the respective switches based on the control clocks φ1 and φ2 and the control signals φA and φB cause the differential voltage between the output signals SOUTP and SOUTN (i.e., the differential signal (SOUTP-SOUTN)) to be converted into a digital signal S14.

### Second Embodiment

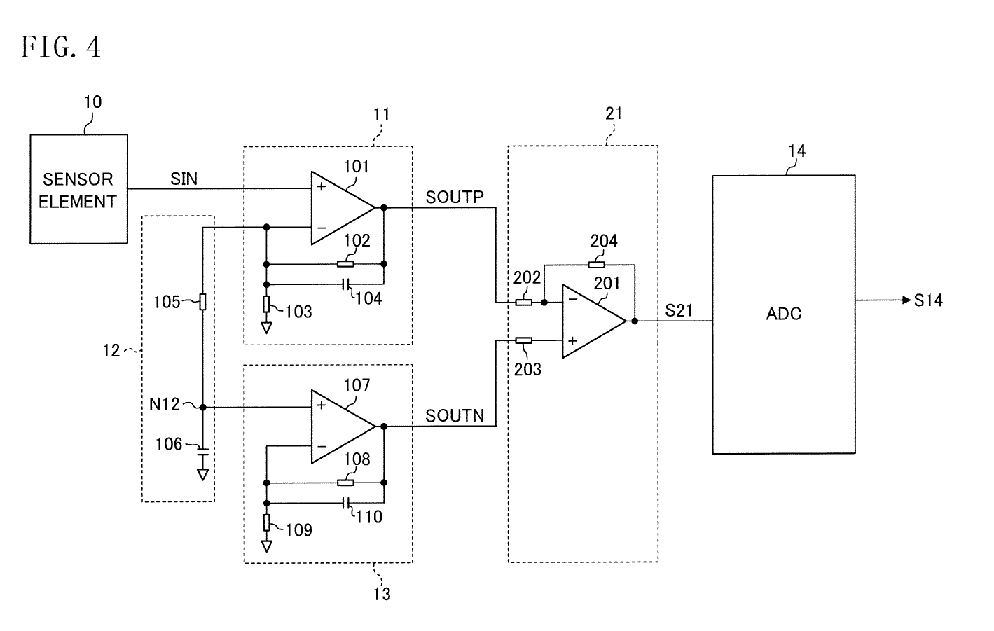

FIG. 4 illustrates an example configuration of an amplifier device according to the second embodiment. This amplifier device includes a differential amplifier circuit 21 in addition to the components shown in FIG. 1. The differential amplifier circuit 21 outputs an output signal S21 which depends on the differential voltage between the output signals SOUTP and SOUTN (i.e., the differential signal (SOUTP-SOUTN)). For example, the differential amplifier circuit 21 includes an operational amplifier 201, a resistor 202 connected between the output terminal of the operational amplifier 101 and the inverting input terminal of the operational amplifier 201, a resistor 203 connected between the output terminal of the operational amplifier 107 and the non-inverting input terminal of the operational amplifier 201, and a resistor 204 connected between the output terminal and the inverting input terminal of the operational amplifier 201. The ADC 14 converts the output signal S21 into a digital signal S14. In this way, the differential signal (SOUTP-SOUTN) may be converted into the single output signal S21, and output to the downstream component by the differential amplifier circuit 21.

### Third Embodiment

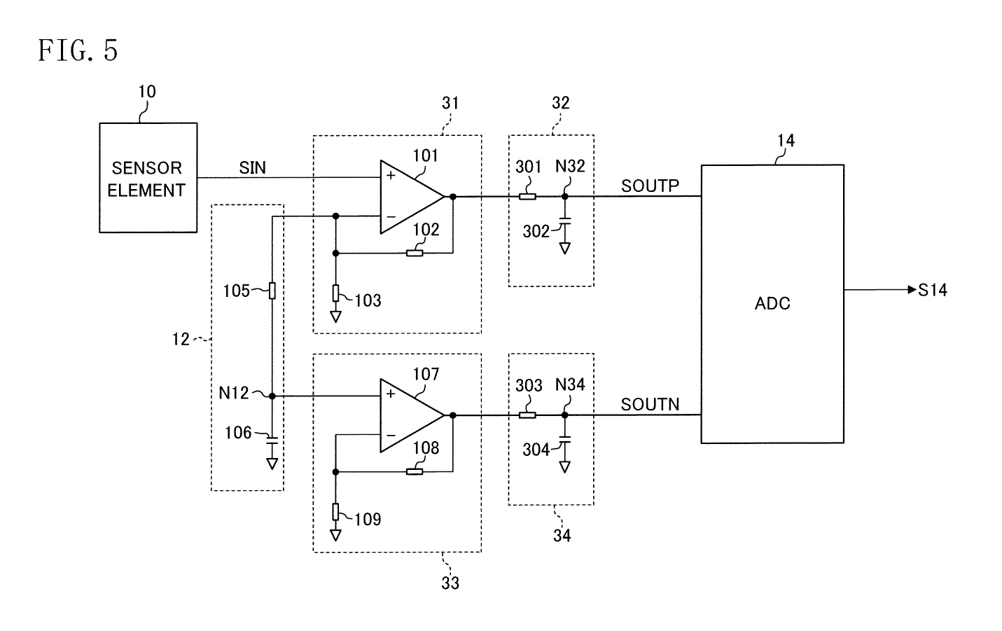

FIG. 5 illustrates an example configuration of an amplifier device according to the third embodiment. This amplifier device includes non-inverting amplifiers 31 and 33, low-pass filter sections 32 and 34, and the low-pass filter circuit 12 shown in FIG. 1.

The non-inverting amplifier 31 includes the operational amplifier 101 and the resistors 102 and 103 shown in FIG. 1. The low-pass filter section 32 includes a resistor 301 connected between the output terminal of the operational amplifier 101 and an output node N32, and a capacitor 302 connected between the output node N32 and a reference node. With this configuration, frequency components lower than a predetermined cut-off frequency (cut-off frequency determined by the resistor 301 and the capacitor 302), of an output signal of the non-inverting amplifier 31 are output from the output node N32 as the output signal SOUTP. The non-inverting amplifier 33 includes the operational amplifier 107 and the resistors 108 and 109 shown in FIG. 1. The low-pass filter section 34 includes a resistor 303 connected between the output terminal of the operational amplifier 107 and an output node N34, and a capacitor 304 connected between the output node N34 and the reference node. With this configuration, frequency components lower than a predetermined cut-off frequency (cut-off frequency determined by the resistor 303 and the capacitor 304), of an output signal of the non-inverting amplifier 33 are output from the output node N34 as the output signal SOUTN.

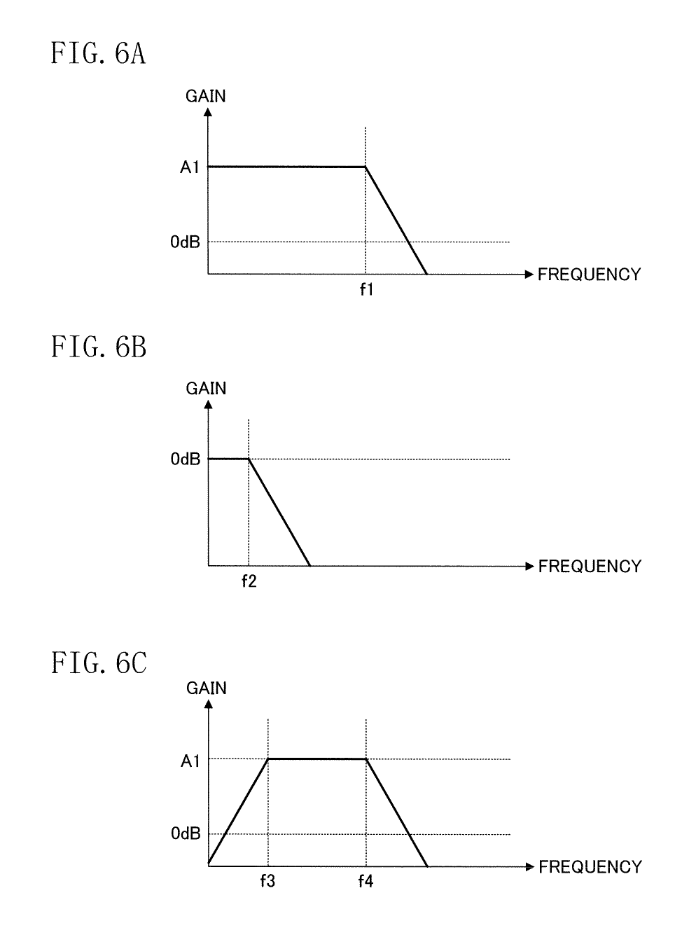

Next, frequency characteristics of the amplifier device shown in FIG. 5 will be described. The DC gain of the low-pass filter circuit (first low-pass filter circuit) including both the non-inverting amplifier 31 and the low-pass filter section 32 is determined by the ratio between the resistors 102 and 103, and the DC gain of the low-pass filter circuit (third low-pass filter circuit) including both the non-inverting amplifier 33 and the low-pass filter section 34 is determined by the ratio between the resistors 108 and 109. Here, it is assumed that as shown in FIG. 6A, the DC gains of the first and the third low-pass filter circuits are each the gain value A1, and the cut-off frequencies of the first and the third low-pass filter circuits are each the frequency f1. In addition, it is assumed that as shown in FIG. 6B, the DC gain of the low-pass filter circuit 12 is 0 dB, and the cut-off frequency thereof is the frequency 12. In such a case, as shown in FIG. 6C, the amplifier device exhibits a frequency characteristic of a bandpass filter. The lower cut-off frequency f3 corresponds to the cut-off frequency f2 of the low-pass filter circuit 12, and the higher cut-off frequency f4 corresponds to the cut-off frequency f1 of the first low-pass filter circuit. Thus, the frequency characteristic of the amplifier device can be set to that of a bandpass filter. That is, the non-inverting amplifier 31 and the low-pass filter section 32 together correspond to the low-pass filter circuit 11 shown in FIG. 1, and the non-inverting amplifier 33 and the low-pass filter section 34 together correspond to the low-pass filter circuit 13 shown in FIG. 1. Note that the DC gains of the first and the third low-pass filter circuits may be different from each other; however, since a larger difference between the DC gains results in a smaller amount of attenuation of low frequency components, it is preferable that the DC gains of the first and the third low-pass filter circuits be the same (or almost the same). Moreover, the cut-off frequencies of the first and the third low-pass filter circuits may be frequencies different from each other.

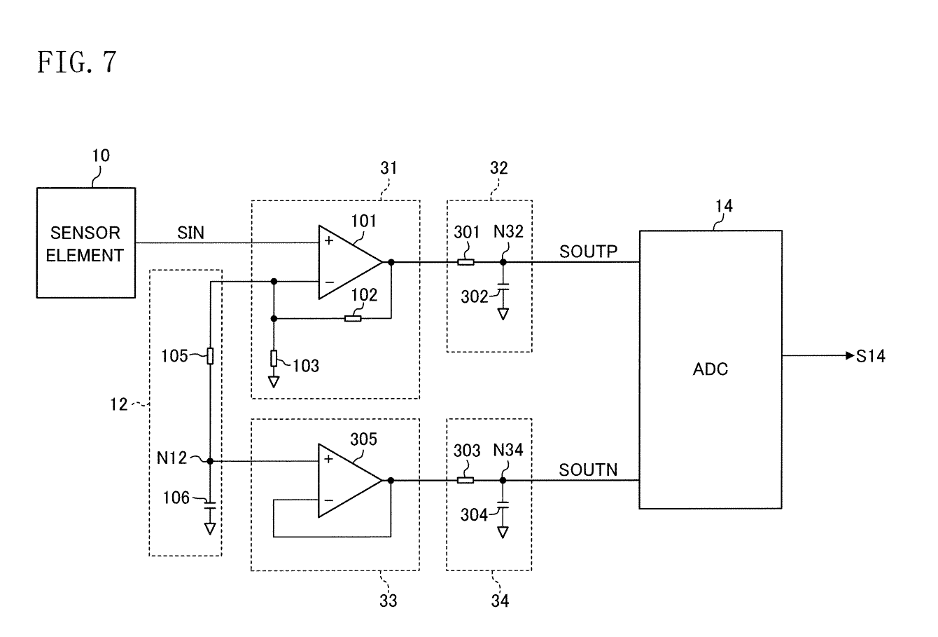

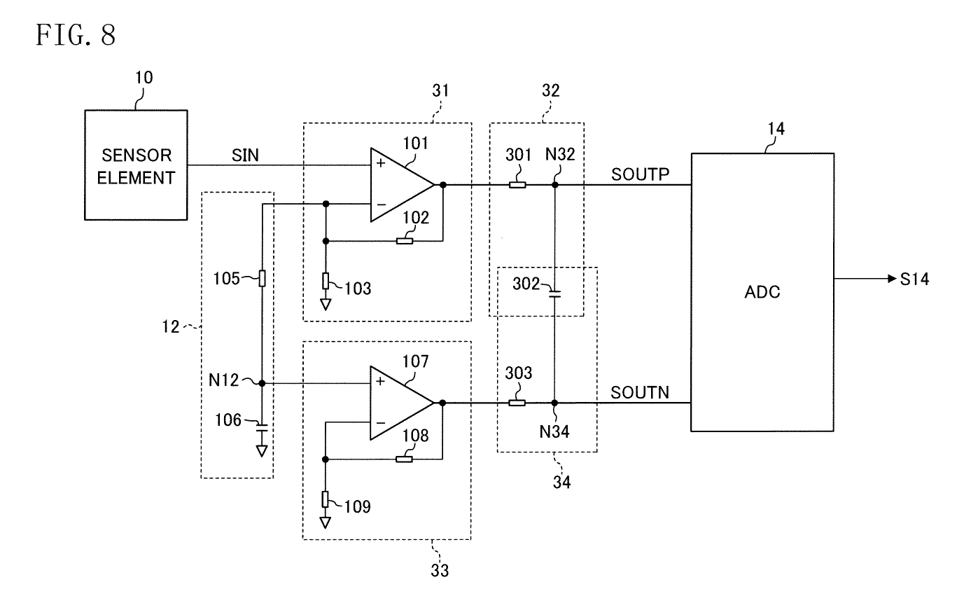

In addition, the amplifier device shown in FIG. 5 may further include the differential amplifier circuit 21 shown in FIG. 4 in addition to the non-inverting amplifiers 31 and 33, the low-pass filter sections 32 and 34, and the low-pass filter circuit 12. Moreover, as shown in FIG. 7, the non-inverting amplifier 33 may be configured using a voltage follower 305. Furthermore, the low-pass filter sections 32 and 34 may each be configured using a first-order low-pass filter such as one shown in FIG. 5, or may each be configured using a second- or higher-order low-pass filter (e.g., a combination of the configuration of the low-pass filter section 32 of FIG. 5 and the configuration of the low-pass filter circuit 11 of FIG. 1). Still furthermore, as shown in FIG. 8, the capacitor 302 of the low-pass filter section 32 and the capacitor 304 of the low-pass filter section 34 may be implemented by a single shared capacitor. In such a case, the capacitor 302 is connected between the output nodes N32 and N34. With such a configuration also, the frequency characteristic of the amplifier device can be set to that of a bandpass filter (FIG. 6C).

Thus, the amplifier devices described above each exhibit a frequency characteristic of a bandpass filter, and thus, are useful for sensor modules etc.

It is to be understood that the foregoing embodiments are illustrative in nature, and are not intended to limit the scope of the invention, application of the invention, or use of the invention.

What is claimed is:

1. An amplifier device for amplifying a sensor signal from a sensor, comprising:
a first low-pass filter circuit having a first input terminal which receives the sensor signal, a second input terminal, and an output terminal which outputs a first output signal;
a second low-pass filter circuit having an input terminal connected to the second input terminal of the first low-pass filter circuit, and an output terminal; and
a third low-pass filter circuit having an input terminal connected to the output terminal of the second low-pass filter circuit, and an output terminal which outputs a second output signal.

2. The amplifier device of claim 1, wherein
the first low-pass filter circuit is an active filter,
the second low-pass filter circuit is a passive filter, and
the third low-pass filter circuit is an active filter.

3. The amplifier device of claim 2, wherein
the first low-pass filter circuit amplifies frequency components lower than a first cut-off frequency, of a differential voltage signal which depends on a voltage difference between signals respectively provided to the first and the second input terminals of the first low-pass filter circuit, and outputs a resultant signal through the output terminal of the first low-pass filter circuit as the first output signal,
the second low-pass filter circuit outputs frequency components lower than a second cut-off frequency, of a signal provided to the input terminal of the second low-pass filter circuit, through the output terminal of the second low-pass filter circuit, and the third low-pass filter circuit amplifies frequency components lower than a third cut-off frequency, of a signal provided to the input terminal of the third low-pass filter circuit, and outputs a resultant signal through the output terminal of the third low-pass filter circuit as the second output signal.

4. The amplifier device of claim 3, wherein
the first low-pass filter circuit includes
a first operational amplifier having a non-inverting input terminal which receives the sensor signal, an inverting input terminal, and an output terminal which outputs the first output signal,
a first resistor and a first capacitor connected in parallel with each other between the output terminal and the inverting input terminal of the first operational amplifier, and
a second resistor connected between the inverting input terminal of the first operational amplifier and a reference node,
the second low-pass filter circuit includes
a third resistor connected between the inverting input terminal of the first operational amplifier and an output node, and
a second capacitor connected between the output node and the reference node, and
the third low-pass filter circuit includes
a second operational amplifier having a non-inverting input terminal connected to the output node, an inverting input terminal, and an output terminal which outputs the second output signal,
a fourth resistor and a third capacitor connected in parallel with each other between the output terminal and the inverting input terminal of the second operational amplifier, and
a fifth resistor connected between the inverting input terminal of the second operational amplifier and the reference node.

5. The amplifier device of claim 3, wherein
the first low-pass filter circuit includes
a first non-inverting amplifier having a non-inverting input terminal which receives the sensor signal, and
a first low-pass filter section configured to output frequency components lower than the first cut-off frequency, of an output signal of the first non-inverting amplifier, as the first output signal,
the second low-pass filter circuit includes
a resistor connected between the inverting input terminal of the first non-inverting amplifier and an output node, and
a capacitor connected between the output node and a reference node, and the third low-pass filter circuit includes
a second non-inverting amplifier having a non-inverting input terminal connected to the output node, and
a second low-pass filter section configured to output frequency components lower than the third cut-off frequency, of an output signal of the second non-inverting amplifier, as the second output signal.

6. The amplifier device of claim 1, further comprising:
a differential amplifier circuit configured to output a third output signal which depends on a differential voltage between the first and the second output signals.

7. A sensor module, comprising:
the amplifier device of claim 1; and
an analog-to-digital converter configured to convert the first and the second output signals into a digital signal which depends on a differential voltage between the first and the second output signals.

8. A sensor module, comprising:
the amplifier device of claim 6; and
an analog-to-digital converter configured to convert the third output signal into a digital signal.
